(19) United States
(12) Patent Application Publication
(10) Pub. No.: US 2026/0231415 A1
(43) Pub. Date: Aug. 6, 2026

(54) PILLAR-EMBEDDED AND INTEGRATED SELECT TRANSISTORS

(71) Applicant: Micron Technology, Inc., Boise, ID (US)

(72) Inventors: Darwin A. Clampitt, Wilder, ID (US); Matthew J. King, Boise, ID (US); Collin Robert Howder, Boise, ID (US)

(21) Appl. No.: 19/437,934

(22) Filed: Dec. 31, 2025

Related U.S. Application Data
(60) Provisional application No. 63/751,119, filed on Jan. 29, 2025.

(51) Int. Cl. H10B 43/27; G11C 5/06; G11C 16/04; H10B 43/10; H10B 43/35; H10W 20/00

(52) U.S. Cl. CPC H10B 43/27; G11C 5/063; G11C 16/0483; H10B 43/10; H10B 43/35; H10W 20/056

(57) ABSTRACT

Methods, systems, and devices for pillar-embedded and integrated select transistors are described. A memory die may include a substrate, a layered material stack over the substrate, and multiple pillars within the layered material stack. The pillars may be distributed throughout the layered material stack with a first pillar of the pillars positioned centrally relative to other pillars of the plurality of pillars. Each pillar may include multiple memory cells, and a select transistor coupled with the memory cells and a bit line. The select transistor may be configured to selectively couple the memory cells with the bit line. The memory die may also include multiple gate contacts formed within a spaces between the pillars. Each gate contact may be coupled with a respective gate of multiple select transistors of the pillars.

### CROSS REFERENCE

The present Application for Patent claims priority to U.S. Patent Application No. 63/751,119 by Clampitt et al., entitled “PILLAR-EMBEDDED AND INTEGRATED SELECT TRANSISTORS,” filed January 29, 2025, which is assigned to the assignee hereof, and which is expressly incorporated by reference in its entirety herein.

### TECHNICAL FIELD

The following relates to one or more systems for memory, including pillar-embedded and integrated select transistors.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a memory system that supports pillar-embedded and integrated select transistors in accordance with examples as disclosed herein.

FIG. 2 shows an example of a memory architecture that supports pillar-embedded and integrated select transistors in accordance with examples as disclosed herein.

FIG. 3 shows an example of a material that supports pillar-embedded and integrated select transistors in accordance with examples as disclosed herein.

FIGS. 4A through 17B show examples and cross-sectional views of material structures that supports pillar-embedded and integrated select transistors in accordance with examples as disclosed herein.

FIG. 18 shows a flowchart illustrating a method or methods that support pillar-embedded and integrated select transistors in accordance with examples as disclosed herein.

### DETAILED DESCRIPTION

A memory die may be formed as a three-dimensional structure that includes strings or stacks of memory cells. In some examples, drain select gates (which may also be referred to as “SGDs”) may be positioned above respective strings of memory cells. Formation of such memory dies may involve forming pillars that are partitioned into subblocks (e.g., by a weaved trench). In some examples, the weaved trench may be formed after the SGDs and memory cells are formed. Such memory dies may also include one or more plugs to connect the memory cells to respective SGDs and to connect the respective SGDs to respective bit lines. Additionally, such memory dies may include segmented (e.g., stacked) conductors that are used to activate the SGDs.

But, in some examples, the process for forming the weaved trench etches or clips the previously formed SGDs. Also, in some examples, the weaved trench can be over-etched (e.g., too deep) or under-etched (e.g., too shallow), and a difficulty associated with preventing over or under-etching may be high. In some examples, the difficulties associated with forming the weaved trench causes shorts between SGDs. Additionally, the plugs used to connect the memory cells to the SGDs and the SGDs to the bit lines may add capacitance into the memory system, which may increase a programming time for the memory cells. Thus, implementations that support lower-capacitance and more reliable formation of SGDs may be desired.

To support lower-capacitance and more reliable formation of SGDs, a top-down process for forming SGDs in a memory die may be utilized. The top-down process for forming SGDs may include performing an initial SGD subblock segmentation operation prior to pillar and SGD formation. The top-down process may include a top-down operation for forming the SGDs via the spaces between the formed pillars. The top-down process may result in the formation of a memory die that has an upper row of SGDs (accessible by an upper row of embedded gate contacts) embedded in the spaces between the formed pillars, where respective strings of memory cells may be coupled with respective SGDs of the upper row of SGDs. The memory die may have an upper row of low-capacitance drain contacts, where respective low-capacitance drain contacts may be coupled with respective SGDs.

In addition to applicability in memory systems as described herein, techniques associated with pillar-embedded and integrated select transistors may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing bit line capacitance, which may decrease processing or latency times, and simplifying manufacturing processes, which may reduce manufacturing costs, among other benefits.

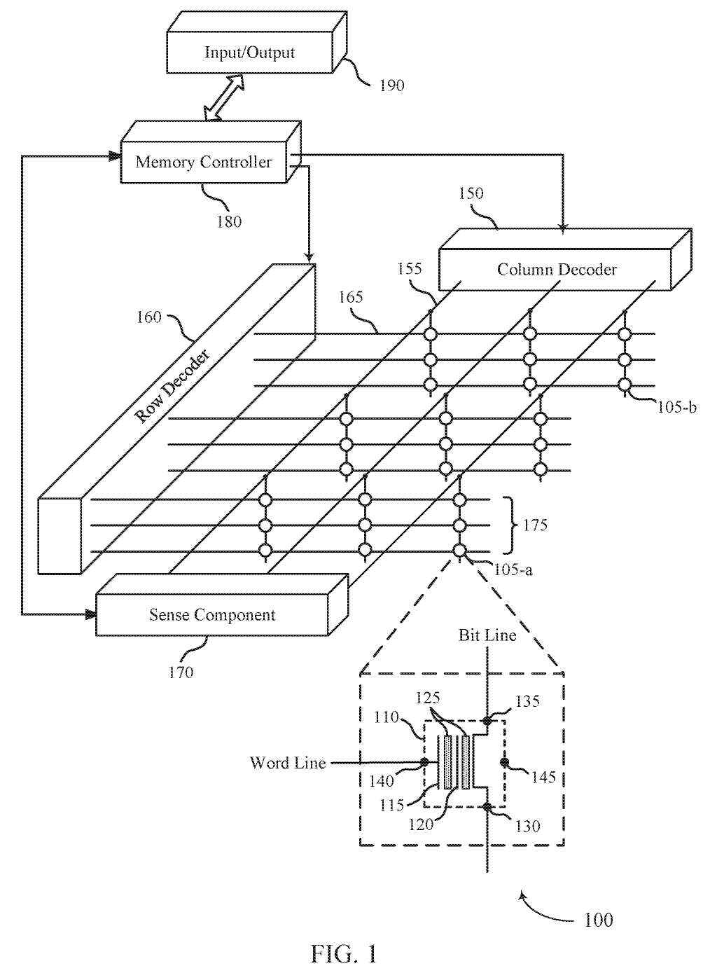

FIG. 1 shows an example of a memory system 100 that supports pillar-embedded and integrated select transistors in accordance with examples as disclosed herein. FIG. 1 is an illustrative representation of various components and features of the memory system 100. As such, the components and features of the memory system 100 are shown to illustrate functional interrelationships, and not necessarily physical positions within the memory system 100. Further, although some elements included in FIG. 1 are labeled with a numeric indicator, some other corresponding elements are not labeled, even though they are the same or would be understood to be similar, in an effort to increase visibility and clarity of the depicted features.

The memory system 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120 or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another and may be generically referred to as access lines or select lines.

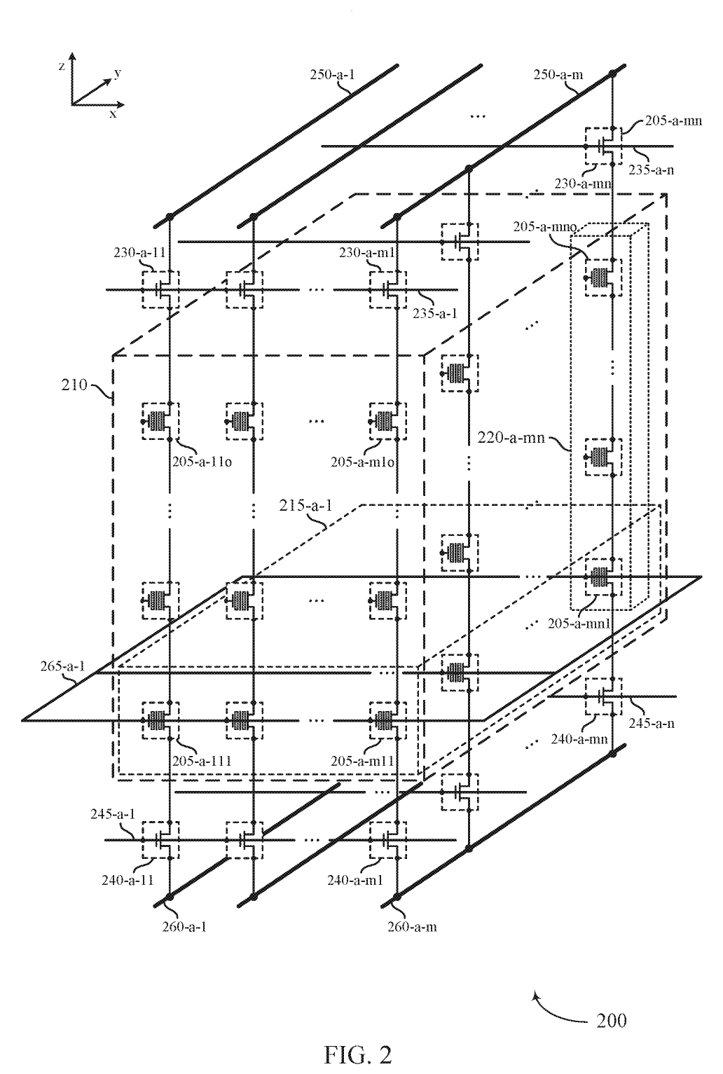

In some cases, a memory system 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory system 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory system 100.

A memory system may include one or more memory dies containing the memory cells 105. In some examples, a memory die may include a stack of materials on a substrate, where multiple pillars may be present within the stack of materials. The pillars may be distributed (e.g., uniformly) throughout the stack of materials (e.g., where the plurality of pillars may be uniformly distributed throughout the stack of materials with a first pillar of the plurality of pillars is positioned centrally relative to other pillars of the plurality of pillars such as in a honeycomb-like pattern), and each pillar may include a stack of memory cells and a select transistor coupled with the stack of memory cells and a bit line. The select transistor may be configured to selectively couple the plurality of memory cells with the bit line. The memory die may also include multiple gate contacts formed within spaces between the pillars. The select transistors may similarly be formed within the spaces between the pillars, and the gate contacts may be coupled with gates of the select transistors.

FIG. 2 shows an example of a memory architecture 200 that supports pillar-embedded and integrated select transistors in accordance with examples as disclosed herein. The memory architecture 200 may be an example of a portion of a memory system, such as a memory system 100. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they would be understood by a person having ordinary skill in the art to be the same as or similar to the labeled elements. Aspects of the memory architecture 200 may be described with reference to an x-direction, a y-direction, and a z-direction of the illustrated coordinate system.

The memory architecture 200 includes a three-dimensional array of memory cells 205, which may be examples of memory cells 105 described with reference to FIG. 1 (e.g., transistors 110, NAND memory cells). In some examples, the memory cells 205 may be connected in a 3D NAND configuration. For example, the memory cells 205 may be included in a block 210, which may be arranged as a 3D array of m memory cells along the x-direction, n memory cells along the y-direction, and o memory cells along the z-direction. Each memory cell 205 may be located (e.g., addressed) in accordance with an index i along the x-direction, an index j along the y-direction, and an index k along the z-direction (e.g., for locating a memory cell 205-a-ijk). A memory system 100 may include any quantity of one or more blocks 210 in accordance with examples as disclosed herein, and different blocks 210 may be adjacent along the x-direction, along the y-direction, or along the z-direction, or any combination thereof.

In the example of memory architecture 200, the block 210 may be divided into a set of pages 215 (e.g., a quantity of o pages 215) along the z-direction, including a page 215-a-1 associated with memory cells 205-a-111 through 205-a-mn1. In some examples, each page 215 may be associated with the same word line 265, (e.g., a word line 165 described with reference to FIG. 1), which may be coupled with a control gate 115 of each of the memory cells 205 of the page 215. For example, page 215-a-1 may be associated with a word line 265-a-1, and other pages 215-a-i may be associated with a different respective word line 265-a-i (not shown). In some examples, a word line 265 in accordance with the memory architecture 200 may be implemented as planar conductor (e.g., in an xy-plane) that is coupled with each of the memory cells 205 of the page 215.

In the example of memory architecture 200, the block 210 also may be divided into a set of strings 220 (e.g., a quantity of (m x n) strings 220) in an xy-plane, including a string 220-a-mn associated with memory cells 205-a-mn1 through 205-a-mno. In some examples, each string 220 may include a set of memory cells 205 connected in series (e.g., along the z-direction, in which a drain of one memory cell 205 in the string 220 may be coupled with a source of another memory cell 205 in the string 220). In some examples, memory cells 205 of a string 220 may be implemented along a common channel, such as a pillar channel (e.g., a columnar channel, a pillar of doped semiconductor) along the z-direction. Each memory cell 205 in a string 220 may be associated with a different word line 265, such that a quantity of word lines 265 in the memory architecture 200 may be equal to the quantity of memory cells 205 in a string 220. Accordingly, a string 220 may include memory cells 205 from multiple pages 215, and a page 215 may include memory cells 205 from multiple strings 220.

In some examples, memory cells 205 may be programmed (e.g., set to a logic 0 value) and read from in accordance with a granularity, such as at the granularity of a page 215 or portion thereof, but may not be erasable (e.g., reset to a logic 1 value) in accordance with the granularity, such as the granularity of a page 215 or portion thereof. For example, NAND memory may instead be erasable in accordance with a different (e.g., higher) level of granularity, such as at the level of granularity the block 210. In some cases, a memory cell 205 may be erased before it may be re-programmed. Different memory devices may have different read, write, or erase characteristics.

In some examples, each string 220 of a block 210 may be coupled with a respective transistor 230 (e.g., a string select transistor, a drain select transistor) at one end of the string 220 (e.g., along the z-direction) and a respective transistor 240 (e.g., a source select transistor, a ground select transistor) at the other end of the string 220. In some examples, a drain of each transistor 230 may be coupled with a bit line 250 of a set of bit lines 250 associated with the block 210, where the bit lines 250 may be examples of bit lines 155 described with reference to FIG. 1. A gate of each transistor 230 may be coupled with a select line 235 (e.g., a string select line, a drain select line). Thus, a transistor 230 may be used to couple a string 220 with a bit line 250 based on applying a voltage to the select line 235, and thus to the gate of the transistor 230. Although illustrated as separate lines along the x-direction, in some examples, select lines 235 may be common to all the transistors 230 associated with the block 210 (e.g., a commonly biased string select node). For example, like the word lines 265 of the block 210, select lines 235 associated with the block 210 may, in some examples, be implemented as a planar conductor (e.g., in an xy-plane) that is coupled with each of the transistors 230 associated with the block 210.

In some examples, a source of each transistor 240 associated with the block 210 may be coupled with a source line 260 of a set of source lines 260 associated with the block 210. In some examples, the set of source lines 260 may be associated with a common source node (e.g., a ground node) corresponding to the block 210. A gate of each transistor 240 may be coupled with a select line 245 (e.g., a source select line, a ground select line). Thus, a transistor 240 may be used to couple a string 220 with a source line 260 based on applying a voltage to the select line 245, and thus to the gate of the transistor 240. Although illustrated as separate lines along the x-direction, in some examples, select lines 245 also may be common to all the transistors 240 associated with the block 210 (e.g., a commonly biased ground select node). For example, like the word lines 265 of the block 210, select lines 245 associated with the block 210 may, in some examples, be implemented as a planar conductor (e.g., in an xy-plane) that is coupled with each of the transistors 240 associated with the block 210.

To operate the memory architecture 200 (e.g., to perform a program operation, a read operation, or an erase operation on one or more memory cells 205 of the block 210), various voltages may be applied to one or more select lines 235 (e.g., to the gate of the transistors 230), to one or more bit lines 250 (e.g., to the drain of one or more transistors 230), to one or more word lines 265, to one or more select lines 245 (e.g., to the gate of the transistors 240), to one or more source lines 260 (e.g., to the source of the transistors 240), or to a bulk for the memory cells 205 (not shown) of the block 210. In some cases, each memory cell 205 of a block 210 may have a common bulk, the voltage of which may be controlled independently of bulks for other blocks 210.

In some cases, as part of a read operation for a memory cell 205, a positive voltage may be applied to the corresponding bit line 250 while the corresponding source line 260 may be grounded or otherwise biased at a voltage lower than the voltage applied to the bit line 250. In some examples, voltages may be concurrently applied to the select line 235 and the select line 245 that are above the threshold voltages of the transistor 230 and the transistor 240, respectively, for the memory cell 205, thereby activating the transistor 230 and transistor 240 such that a channel associated with the string 220 that includes the memory cell 205 (e.g., a pillar channel) may be electrically connected with (e.g., electrically connected between) the corresponding bit line 250 and source line 260. A channel may be an electrical path through the memory cells 205 in the string 220 (e.g., through the sources and drains of the transistors in the memory cells 205 of the string 220) that may conduct current under some operating conditions.

In some examples, multiple word lines 265 (e.g., in some cases all word lines 265) of the block 210—except a word line 265 associated with a page 215 of the memory cell 205 to be read—may concurrently be set to a voltage (e.g., VREAD) that is higher than the threshold voltage (VT) of the memory cells 205. VREAD may cause all memory cells 205 in the unselected pages 215 be activated so that each unselected memory cell 205 in the string 220 may maintain high conductivity within the channel. In some examples, the word line 265 associated with the memory cell 205 to be read may be set to a voltage, VTarget. Where the memory cells 205 are operated as SLC memory cells, VTarget may be a voltage that is between (i) VT of a memory cell 205 in an erased state and (ii) VT of a memory cell 205 in a programmed state.

When the memory cell 205 to be read exhibits an erased VT (e.g., VTarget > VT of the memory cell 205), the memory cell 205 may turn “ON” in response to the application of VTarget to the word line 265 of the selected page 215, which may allow a current to flow in the channel of the string 220, and thus from the bit line 250 to the source line 260. When the memory cell 205 to be read exhibits a programmed VT (e.g., VTarget < VT of the selected memory cell), the memory cell 205 may remain “OFF” despite the application of VTarget to the word line 265 of the selected page 215, and thus may prevent a current from flowing in the channel of the string 220, and thus from the bit line 250 to the source line 260.

A signal on the bit line 250 for the memory cell 205 (e.g., an amount of current below or above a threshold) may be sensed (e.g., by a sense component 170 as described with reference to FIG. 1), and may indicate whether the memory cell 205 became conductive or remained non-conductive in response to the application of VTarget to the word line 265 of the selected page 215. The sensed signal thus may be indicative of whether the memory cell 205 was in an erased state (e.g., storing a logic 1) or a programmed state (e.g., storing a logic 0). Though aspects of the example read operation above have been explained in the context of an SLC memory cell 205 for clarity, such techniques may be extended or altered and applied in the context of a multiple-level memory cell 205 (e.g., through the use of multiple values of VTarget corresponding to the different amounts of charge that may be stored in one multiple-level memory cell 205).

In some cases, as part of a program operation for a memory cell 205, charge may be added to a portion of the memory cell 205 such that current flow through the memory cell 205, and thus the corresponding string 220, may be inhibited when the memory cell 205 is later read. For example, charge may be injected into a charge trapping structure 120 as shown in memory cell 105-a of FIG. 1. In some cases, respective voltages may be applied to the word line 265 of the page 215 and the bulk of the memory cell 205 to be programmed such that a control gate 115 of the memory cell 205 is at a higher voltage than the bulk of the memory cell 205 (e.g., a positive voltage may be applied to the word line). Concurrently, voltages may be applied to the select line 235 and the select line 245 that are above the threshold voltages of the transistor 230 and the transistor 240, respectively, thereby activating the transistor 230 and the transistor 240, and the bit line 250 for the memory cell 205 to be programmed may be set to a relatively high voltage. This may cause an electric field such that electrons are pulled from the source of the memory cell 205 towards the drain. The electric field may also cause some of these electrons to be pulled through dielectric material 125 and thereby injected into the charge trapping structure 120 of the memory cell 205, through a process which may in some cases be referred to as tunnel injection.

In some cases, a single program operation may program some or all memory cells 205 in a page 215, as the memory cells 205 of the page 215 may all share a common word line 265 and a common bulk. For a memory cell 205 of the page 215 for which it is not desired to write a logic 0 (e.g., not desired to program the memory cell 205), the corresponding bit line 250 may be set to a relatively low voltage (e.g., ground), which may inhibit the injection of electrons into a charge trapping structure 120. Though aspects of the example program operation above have been explained in the context of an SLC memory cell 205 for clarity, such techniques may be extended and applied to the context of a multiple-level memory cell 205 (e.g., through the use of multiple programming voltages applied to the word line 265, or multiple passes or pulses of a programming voltage applied to the word line 265, corresponding to the different amounts of charge that may be stored in one multiple-level memory cell 205).

In some cases, as part of an erase operation for a memory cell 205, charge may be removed from a portion of the memory cell 205 such that current flow through the memory cell 205, and thus the corresponding string 220, may be uninhibited (e.g., allowed, at least to a greater extent) when the memory cell 205 is later read. For example, charge may be removed from a charge trapping structure 120 as shown in memory cell 105-a of FIG. 1. In some cases, respective voltages may be applied to the word line 265 of the page 215 and the bulk of the memory cell 205 to be erased such that a control gate 115 of the memory cell 205 is at a lower voltage than the bulk of the memory cell 205 (e.g., a positive voltage may be applied to the bulk), which may cause an electric field that pulls electrons out of the charge trapping structure 120 and into the bulk of the memory cell 205. In some cases, a single program operation may erase all memory cells 205 in a block 210, as the memory cells 205 of the block 210 may all share a common bulk.

A memory system may include one or more memory dies. A memory die may include transistors (which may be referred to as drain select gates, SGDs, or select transistors) at the ends of strings of memory cells that may be used to isolate the strings from one another. In some examples, the strings may be included in subblocks of memory, which may be include in blocks of memory.

In some examples, the memory die may be formed as a 3D structure that includes strings or stacks of memory cells, where respective SGDs may be positioned above respective strings of memory cells. Formation of such memory dies may involve forming pillars that are partitioned into subblocks (e.g., by a weaved trench). In some examples, the weaved trench may be formed after the SGDs and memory cells are formed. Such memory dies may also include one or more plugs to connect the memory cells to respective SGDs and to connect the respective SGDs to respective bit lines. Additionally, such memory dies may include segmented (e.g., stacked) conductors that are used to activate the SGDs (e.g., segmented gate contacts configured to activate gates of the SGDs, such that groups of segmented gate contacts are configured to activate respective gates of the SGDs).

But, in some examples, the process for forming the weaved trench etches or clips the previously formed SGDs. Also, in some examples, the weaved trench can be over-etched (e.g., too deep) or under-etched (e.g., too shallow), and a difficulty associated with preventing over or under-etching may be high. In some examples, the difficulties associated with forming the weaved trench causes shorts between SGDs. Additionally, the plugs used to connect the memory cells to the SGDs and the SGDs to the bit lines may add capacitance into the memory system, which may increase a programming time for the memory cells. Thus, implementations (e.g., methods, systems, apparatuses, techniques, configurations, components) that support lower-capacitance and more reliable formation of SGDs may be desired.

To support lower-capacitance and more reliable formation of SGDs, a top-down process for forming SGDs in a memory die may be utilized. The top-down process for forming SGDs may include performing an initial SGD subblock segmentation operation prior to pillar and SGD formation. The top-down process may include a top-down operation for forming the SGDs via the spaces between the formed pillars. The top-down process may result in the formation of a memory die that has an upper row of SGDs (accessible by an upper row of embedded gate contacts) embedded in the spaces between the formed pillars, where respective strings of memory cells may be coupled with respective SGDs of the upper row of SGDs. The memory die may have an upper row of low-capacitance drain contacts, where respective low-capacitance drain contacts may be coupled with respective SGDs.

In some examples, a memory die may include a stack of materials on a substrate and multiple pillars within the stack of materials. The pillars may be distributed throughout the stack of materials (e.g., where the plurality of pillars may be distributed throughout the stack of materials with a first pillar of the plurality of pillars is positioned centrally relative to other pillars of the plurality of pillars such as in a honeycomb-like pattern), and each pillar may include a stack of memory cells (e.g., the memory cell 205-a-11o to the memory cell 205-a-111) and a select transistor (e.g., the transistor 230-a-11) coupled with the stack of memory cells and a bit line (e.g., the bit line 250-a-1). The select transistor may be configured to selectively couple the plurality of memory cells with the bit line. The memory die may also include multiple gate contacts formed within spaces between the pillars. The select transistors may similarly be formed within the spaces between the pillars, and the gate contacts may be coupled with gates of the select transistors.

By performing the SGD subblock segmentation prior to the pillar formation, the SGD subblocks may be performed at a top of the memory die (which may avoid deep etching operations after circuit elements have been formed). Additionally, by forming the SGDs using a top-down operation, the plugs used to connect the memory cells to the SGDs and the plugs used to connect the SGDs to the bit lines may be omitted. Moreover, by omitting the plugs, respective low capacitance drain contacts may be performed to access the drains of respective SGDs, which may support lower latency programming operations. Additionally, the gates of the SGDs and gate contacts for activating the gates of the SGDs may be integrated (rather than de-integrated), which may improve a performance of the SGDs by allowing the integrated gates of the SGDs to be activated in a uniform fashion via the integrated gate contacts.

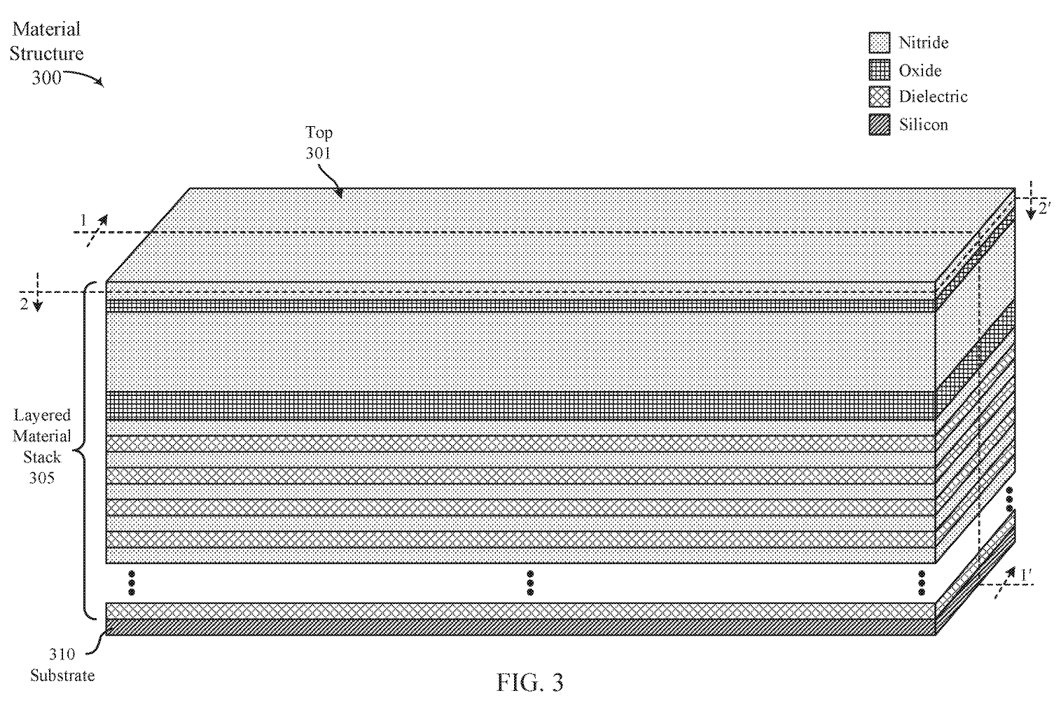

FIG. 3 shows an example of a material structure that supports pillar-embedded and integrated select transistors in accordance with examples as disclosed herein.

The material structure 300 may include the substrate 310 and the layered material stack 305, which may be located above (e.g., on) the substrate 310. The layered material stack 305 may include multiple material layers, such as including dielectric layers, oxide layers, and/or nitride layers. In some examples, the lower layers of the layered material stack 305 may include alternating dielectric and nitride layers and the upper layers of the layered material stack 305 may include alternating nitride and oxide layers. In some examples, the upper layers of the layered material stack 305 include a first nitride layer, a first oxide layer, a second, thickened nitride layer, and a second, thickened oxide layer (e.g., located at the top 301 of the material structure 300).

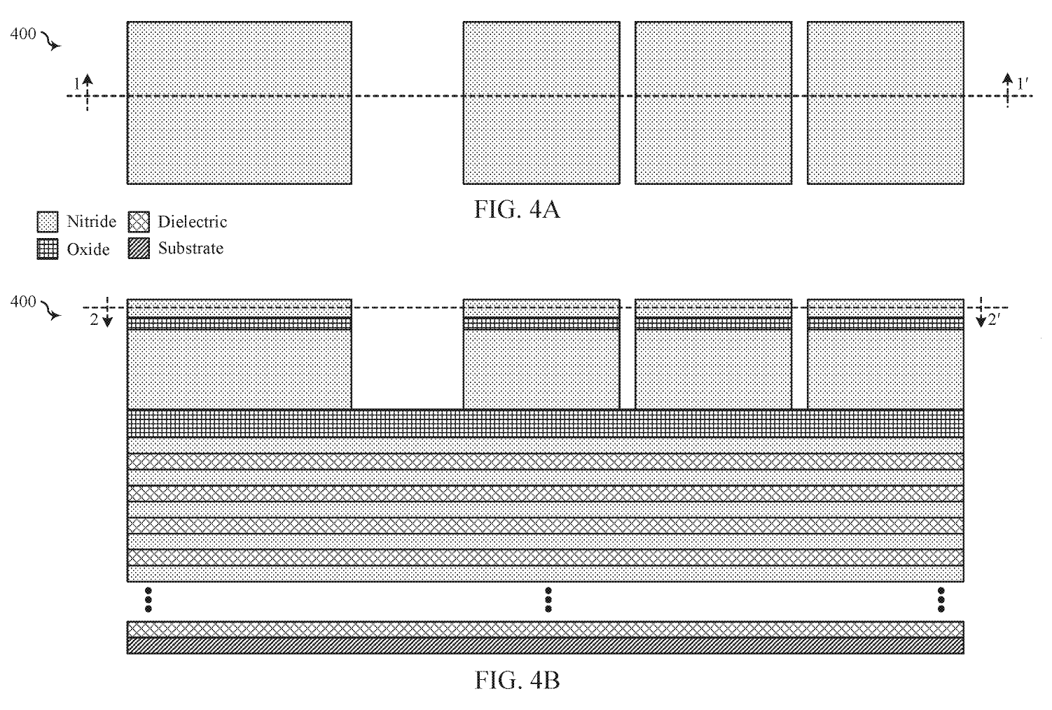

FIGS. 4A and 4B show different cross-sectional views of a material structure that supports pillar-embedded and integrated select transistors in accordance with examples as disclosed herein. FIG. 4A shows a top view of a first cross-section through the material structure 400 indicated by line 2 – 2' (which may correspond to line 2 – 2' in FIG. 3). FIG. 4B shows a front view of a second cross-section through the material structure 400 indicated by line 1 – 1' (which may correspond to line 1 – 1' in FIG. 3).

The material structure 400 may be formed by removing (e.g., etching, patterning, exhuming) sections of the first nitride layer, the first oxide layer, and the second nitride layer in the material structure 300 illustrated in FIG. 3. The removing may be performed in accordance with a planned data block configuration for a memory die to be formed from the material structure 400. In some examples, the removing may result in block and subblock segmentations, which may correspond to block and subblock SGD segmentations.

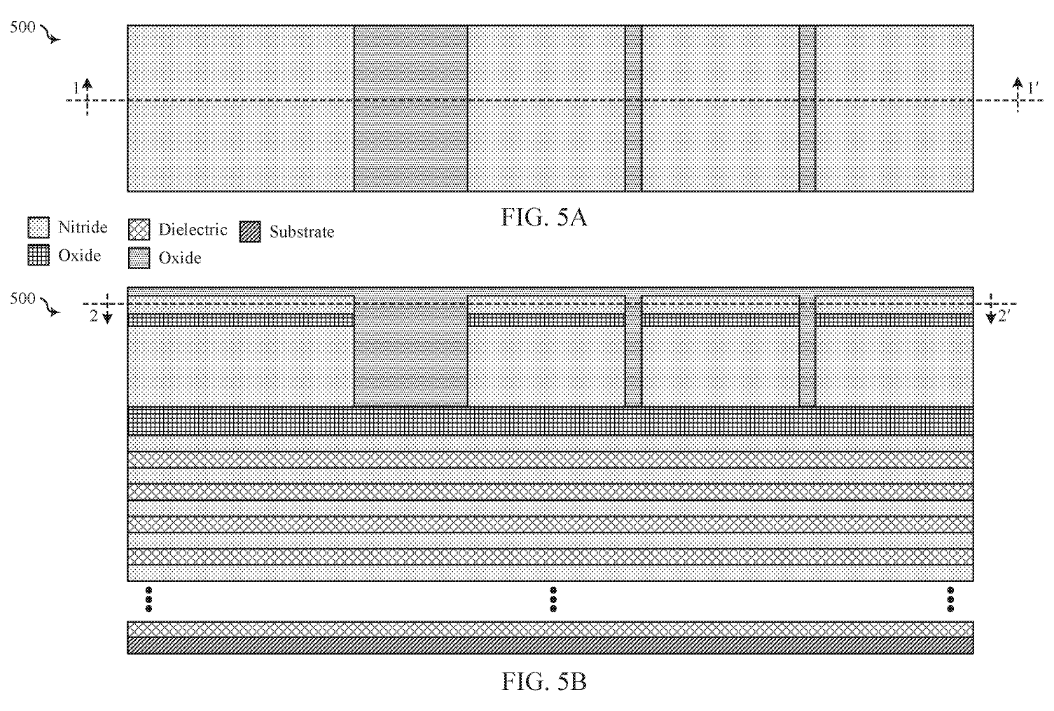

FIGS. 5A and 5B show different cross-sectional views of a material structure that supports pillar-embedded and integrated select transistors in accordance with examples as disclosed herein. FIG. 5A shows a top view of a first cross-section through the material structure 500 indicated by line 2 – 2' (which may correspond to line 2 – 2' in FIG. 3). FIG. 5B shows a front view of a second cross-section through the material structure 500 indicated by line 1 – 1' (which may correspond to line 1 – 1' in FIG. 3).

The material structure 500 may be formed by adding (e.g., depositing, inserting) a protective oxide layer on top of the material structure 400 illustrated in FIGS. 4A and 4B. In some examples, a top of the resulting material structure may be planarized, yielding the material structure 500.

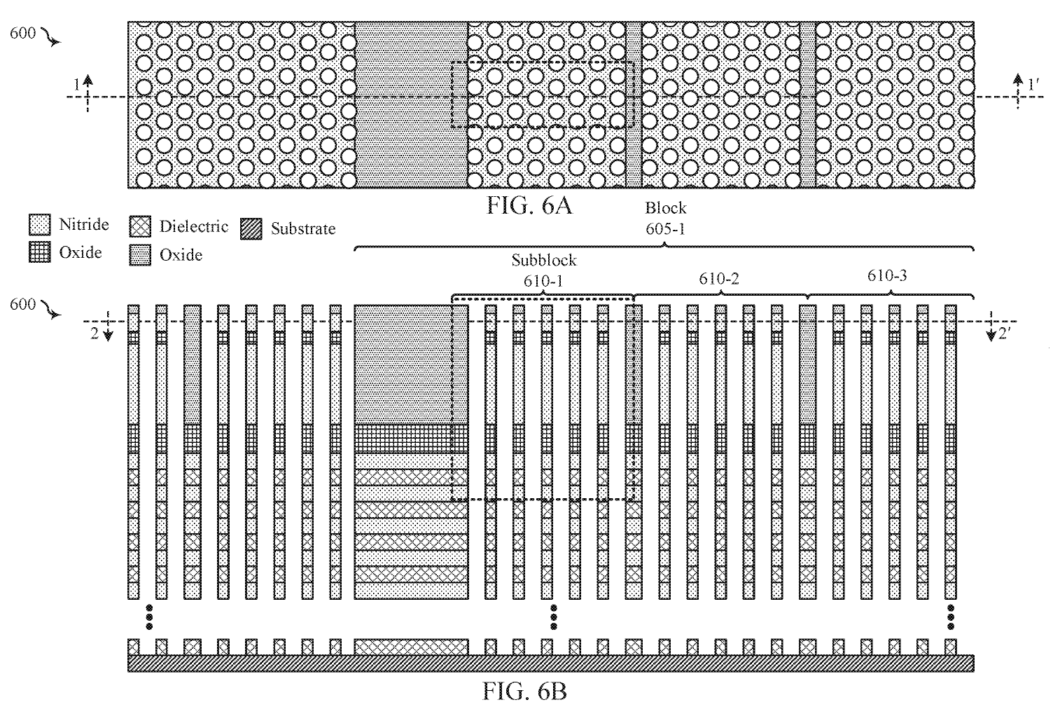

FIGS. 6A and 6B show different cross-sectional views of a material structure that supports pillar-embedded and integrated select transistors in accordance with examples as disclosed herein. FIG. 6A shows a top view of a first cross-section through the material structure 600 indicated by line 2 – 2' (which may correspond to line 2 – 2' in FIG. 3). FIG. 6B shows a front view of a second cross-section through the material structure 600 indicated by line 1 – 1' (which may correspond to line 1 – 1' in FIG. 3).

The material structure 600 may be formed by removing (e.g., etching, patterning, exhuming) sections that extend through the material structure 500 illustrated in FIGS. 5A and 5B (e.g., down to the substrate) to form multiple cylindrical cavities. As depicted in FIG. 6B, blocks, such as the block 605-1, and subblocks, such as the first subblock 610-1, the second subblock 610-2, and the third subblock 610-3, may be delineated after the cylindrical cavities are formed. Etching through the layered material stack to form the blocks and subblocks (as well as the SGD block and SGD subblock segmentations) prior to formation of the select transistor may reduce issues (e.g., shorts) caused by performing the segmentation after the select transistor are formed (e.g., as a result of over etching or under etching the segmenting features).

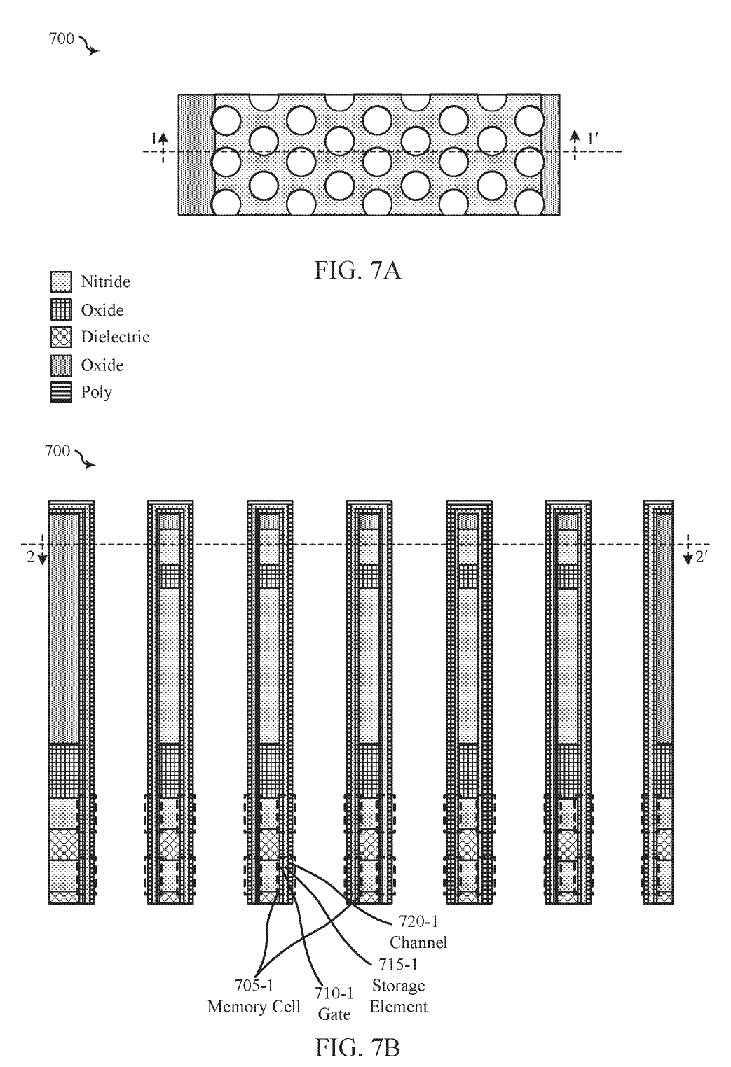

FIGS. 7A and 7B show different cross-sectional views of a material structure that supports pillar-embedded and integrated select transistors in accordance with examples as disclosed herein. FIG. 7A shows a top view of a first cross-section through the material structure 700 indicated by line 2 – 2' (which may correspond to line 2 – 2' in FIG. 3). FIG. 7B shows a front view of a second cross-section through the material structure 700 indicated by line 1 – 1' (which may correspond to line 1 – 1' in FIG. 3).

The material structure 700 may be formed by adding (e.g., depositing, inserting) one or more materials on top of the material structure 600 illustrated in FIGS. 6A and 6B, where the materials may coat an inside of the cylindrical cavities illustrated in FIGS. 6A and 6B. In some examples, a blocking oxide layer, a storage nitride layer, a tunnel oxide layer, and a channel polysilicon layer are added (e.g., deposited, inserted) on top of the material structure 600 (in some examples, in that order or in another order). These layers may form aspects of the channels for the select transistors resulting from the method of formation described herein. These layers may additionally form aspects of the channels, storage elements, and gates for the memory cells resulting from the method of formation described herein. For example, the polysilicon layer may form aspects of a channel for the select transistors and memory cells.

The material structure 700 may include memory cells (such as the first memory cell 705-1), which may be included within strings of memory cells. The strings of memory cells may be located within respective cylindrical cavities, and the strings of memory cells may, thus, be isolated from one another. In some examples, the memory cells may be transistors that include gates, storage elements, and channels (e.g., the first memory cell 705-1 may be a transistor having the first gate 710-1, the first storage element 715-1, and the first channel 720-1).

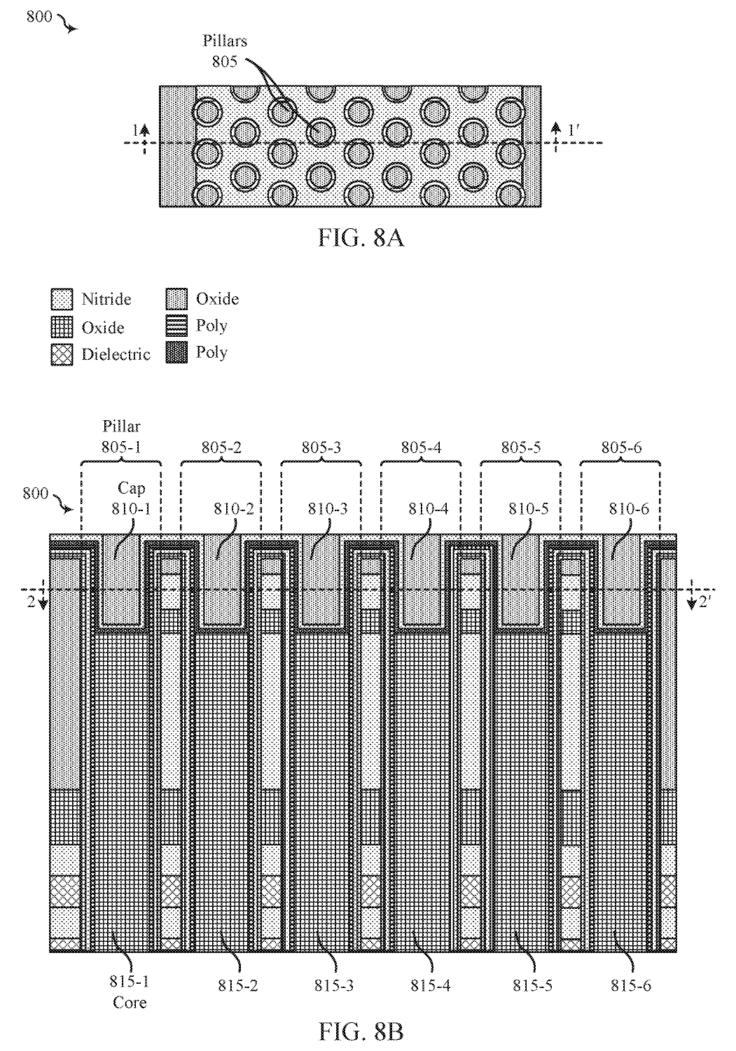

FIGS. 8A and 8B show different cross-sectional views of a material structure that supports pillar-embedded and integrated select transistors in accordance with examples as disclosed herein. FIG. 8A shows a top view of a first cross-section through the material structure 800 indicated by line 2 – 2' (which may correspond to line 2 – 2' in FIG. 3). FIG. 8B shows a front view of a second cross-section through the material structure 800 indicated by line 1 – 1' (which may correspond to line 1 – 1' in FIG. 3).

The material structure 800 may be formed by filling respective portions of the remaining cylindrical cavities illustrated in FIGS. 7A and 7B with a first oxide material. After filling the respective portions, a polysilicon (e.g., an N+ doped polysilicon) layer and a nitride layer (in that order) may be added (e.g., deposited, inserted) on top of the resulting material structure. These layers may form aspects of the drains for the select transistors and the memory cells resulting from the method of formation described herein. For example, the polysilicon layer may form aspects of a drain for the select transistors and memory cells.

Next, cylindrical cavities formed between the nitride layer may be filled with a second oxide material. In some examples, after filling the remaining cylindrical cavities, a top of the resulting material structure may be planarized (e.g., to remove any excess oxide material, to remove a layer of oxide material that exposes portions of the nitride layer, etc.), yielding the material structure 800.

The material structure 800 may include multiple pillars (e.g., the first pillar 805-1 through the sixth pillar 805-6) that extend through the material structure 800 (e.g., down to the substrate). In some examples, the portions of the first oxide material that fill the portions of the remaining cylindrical cavities illustrated in FIGS. 8A and 8B are referred to as cores (e.g., the first core 815-1 through the sixth core 815-6) of the pillars. In some examples, the portions of the second oxide material that fill the remaining cylindrical cavities are referred to as caps (e.g., the first cap 810-1 through the sixth cap 810-6) of the pillars.

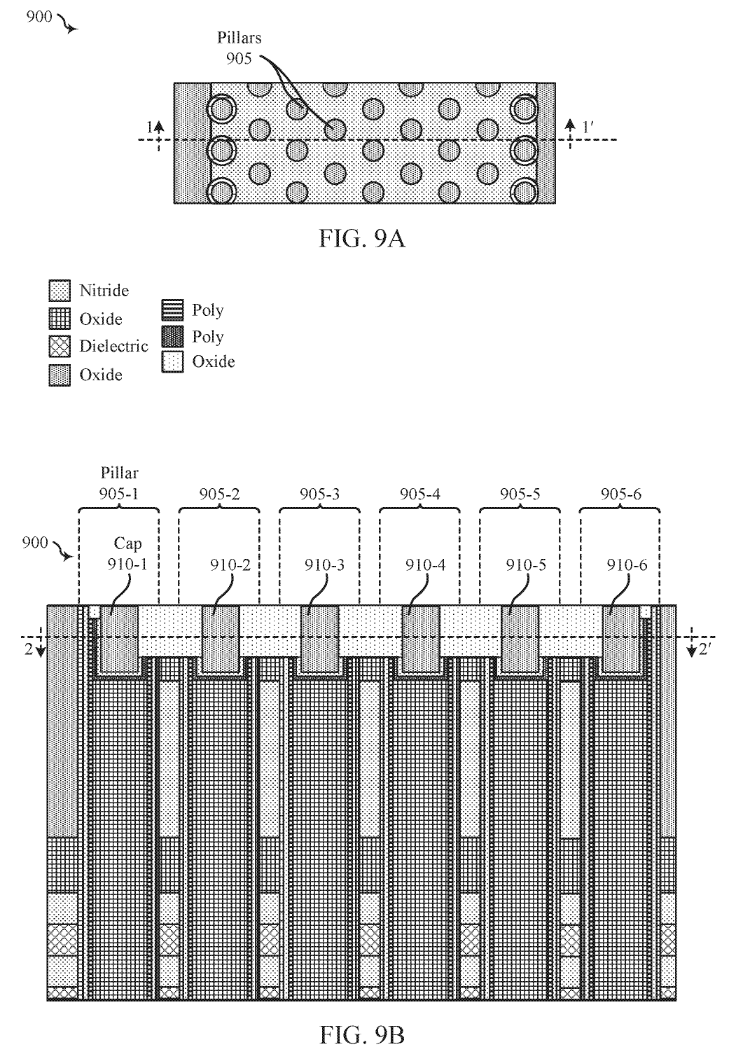

FIGS. 9A and 9B show different cross-sectional views of a material structure that supports pillar-embedded and integrated select transistors in accordance with examples as disclosed herein. FIG. 9A shows a top view of a first cross-section through the material structure 900 indicated by line 2 – 2' (which may correspond to line 2 – 2' in FIG. 3). FIG. 9B shows a front view of a second cross-section through the material structure 900 indicated by line 1 – 1' (which may correspond to line 1 – 1' in FIG. 3).

The material structure 900 may be formed by removing (e.g., etching, patterning, exhuming) portions of the material structure 800 illustrated in FIGS. 8A and 8B to expose portions of the caps 910-1, creating starting and ending cavities on the starting and ending caps and intermediary cavities (larger than the starting and ending cavities) between the caps. The starting cavities, ending cavities, and intermediary cavities may be filled with an oxide material. In some examples, after filling the starting cavities, ending cavities, and intermediary cavities, a top of the resulting material structure may be planarized (e.g., to remove any excess oxide material), yielding the material structure 900.

In some examples, the caps are exposed in stages. For example, in a first stage, the exposed portions of the nitride layer may be removed (e.g., etched, patterned, exhumed) to expose the first polysilicon layer. The exposed portions of the first polysilicon layer may then be removed (e.g., etched, patterned, exhumed) to expose the second polysilicon layer. And the exposed portions of the second polysilicon layer be removed (e.g., etched, patterned, exhumed) to expose the embedded nitride layer. In a second stage, the exposed portions of the embedded nitride layer may be removed (e.g., etched, patterned, exhumed) to expose the oxide layer. The exposed portions of the oxide layer may then be removed (e.g., etched, patterned, exhumed) to expose the nitride layer (which may correspond to the top nitride layer of the layered material stack 305 illustrated in FIG. 3). In a third stage, the top nitride layer may be removed (e.g., etched, patterned, exhumed) to expose the second oxide layer (which may correspond to the top oxide layer of the layered material stack 305 illustrated in FIG. 3). In a fourth stage, exposed portions (e.g., tops) of the blocking oxide and the storage nitride exposed by removing the top nitride layer may be removed (e.g., etched, patterned, exhumed) to expose portions of the channel polysilicon layer and the N+ doped polysilicon layer. In a fifth stage, exposed portions (e.g., tops) of the channel polysilicon layer and the N+ doped polysilicon layer may be removed to expose the embedded nitride layer. And in a sixth stage, exposed portions of the embedded nitride layer may be removed to expose the caps and obtain the material structure 900, absent the oxide material used to fill the starting cavities, ending cavities, and intermediary cavities.

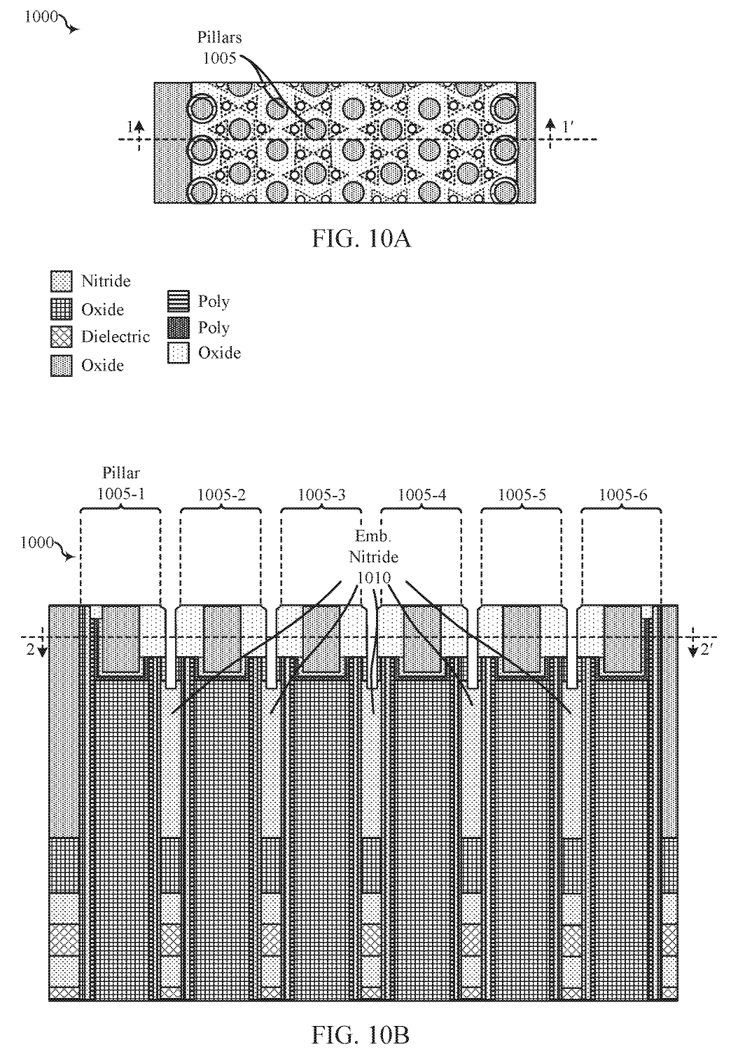

FIGS. 10A and 10B show different cross-sectional views of a material structure that supports pillar-embedded and integrated select transistors in accordance with examples as disclosed herein. FIG. 10A shows a top view of a first cross-section through the material structure 1000 indicated by line 2 – 2' (which may correspond to line 2 – 2' in FIG. 3). FIG. 10B shows a front view of a second cross-section through the material structure 1000 indicated by line 1 – 1' (which may correspond to line 1 – 1' in FIG. 3).

The material structure 1000 may be formed by removing (e.g., etching, patterning, exhuming) cavities in respective areas (e.g., respective triangular area) between the pillars formed in the material structure illustrated in FIGS. 9A and 9B, such that the embedded nitride layer 1010 located between the pillars is exposed.

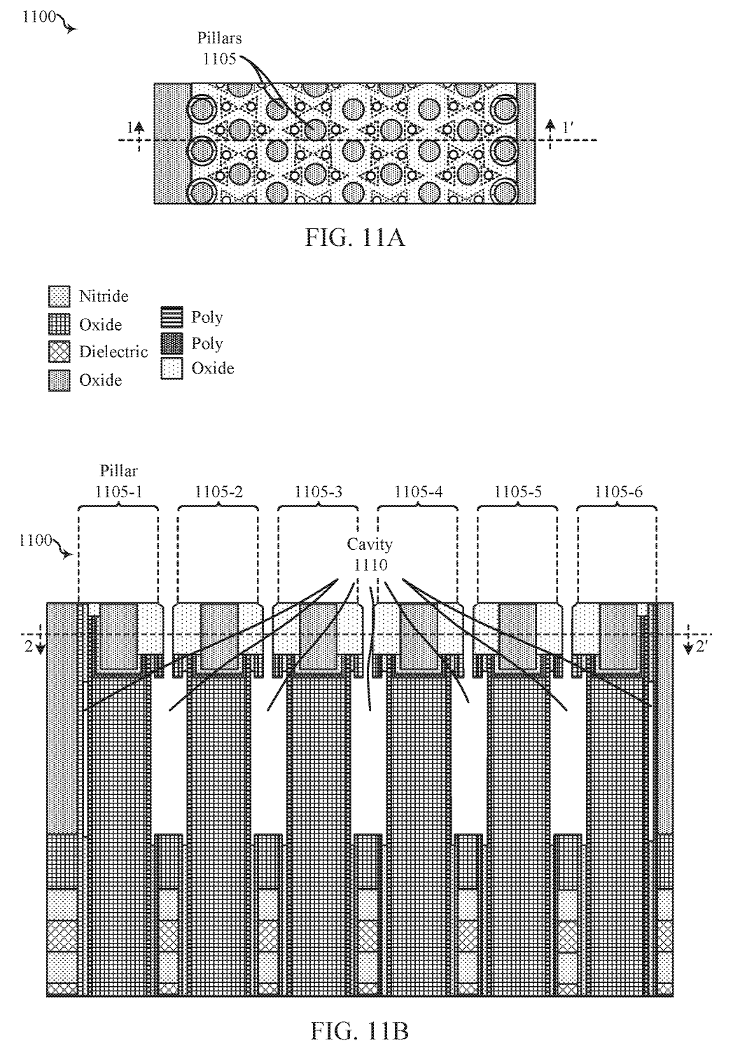

FIGS. 11A and 11B show different cross-sectional views of a material structure that supports pillar-embedded and integrated select transistors in accordance with examples as disclosed herein. FIG. 11A shows a top view of a first cross-section through the material structure 1100 indicated by line 2 – 2' (which may correspond to line 2 – 2' in FIG. 3). FIG. 11B shows a front view of a second cross-section through the material structure 1100 indicated by line 1 – 1' (which may correspond to line 1 – 1' in FIG. 3).

The material structure 1100 may be formed by removing (e.g., etching, patterning, exhuming) the embedded nitride layer (which may correspond to the second-from-the-top nitride layer of the layered material stack 305 illustrated in FIG. 3) from the material structure 1000 illustrated in FIGS. 10A and 10B to expose a portion of the blocking oxide layer. The exposed portion of the blocking oxide layer may then be removed (e.g., etched) to expose the storage nitride layer. And at least the exposed portion of the storage nitride layer may then be removed (e.g., etched) to expose portions of the channel polysilicon layer. As the storage nitride layer is formed around a circumference of the pillars, a process (e.g., a wet etching process) for removing the exposed portion of the storage nitride layer may be configured to extend around the pillars, including where the pillars overlap with the starting and ending oxide layers delineating the block and subblock segmentations. This may allow the cavity 1110 to extend around the outer pillars. In some examples, a result of the etch extends higher and lower within the intermediary cavities than the starting and ending cavities (e.g., to enable the etch to extend around the pillars), which may cause a length of the intermediary cavity to be longer than a length of the starting and ending cavities.

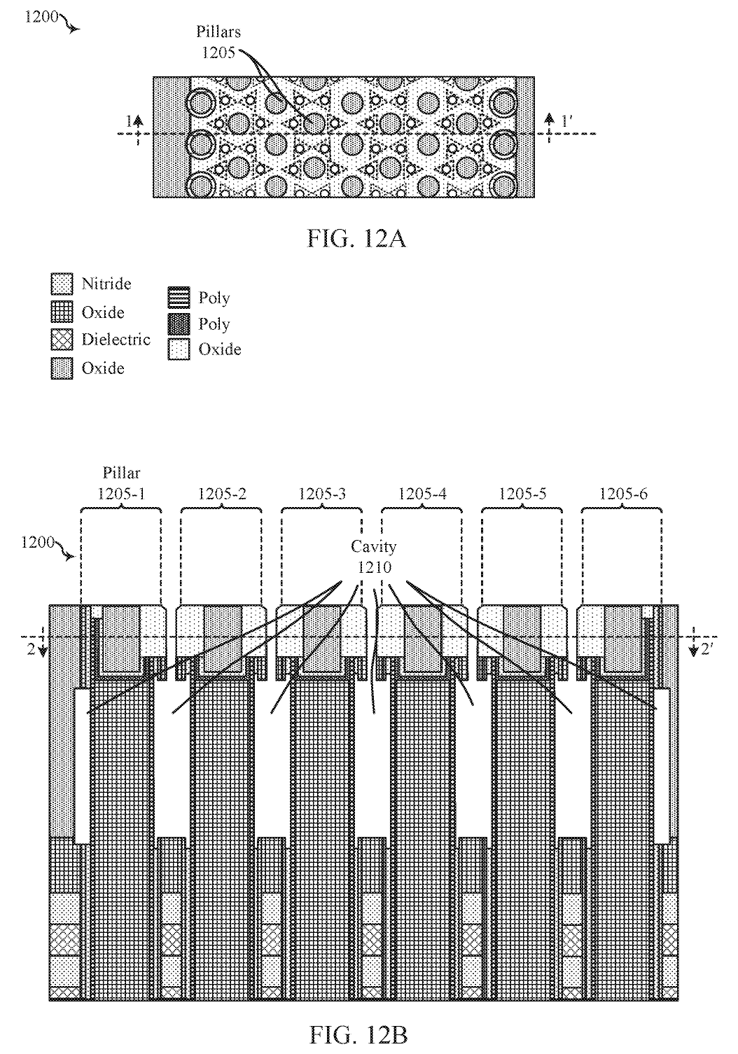

FIGS. 12A and 12B show different cross-sectional views of a material structure that supports pillar-embedded and integrated select transistors in accordance with examples as disclosed herein. FIG. 12A shows a top view of a first cross-section through the material structure 1200 indicated by line 2 – 2' (which may correspond to line 2 – 2' in FIG. 3). FIG. 12B shows a front view of a second cross-section through the material structure 1200 indicated by line 1 – 1' (which may correspond to line 1 – 1' in FIG. 3).

The material structure 1200 may be formed by removing (e.g., etching, patterning, exhuming) additional material (e.g., the oxide material(s) in the segmented portions of the material structure 1200) from the starting and ending cavities — e.g., using the cavity 1110 formed in the material structure 1100 of FIGS. 11A and 11B as an access point — yielding the enlarged cavity 1210.

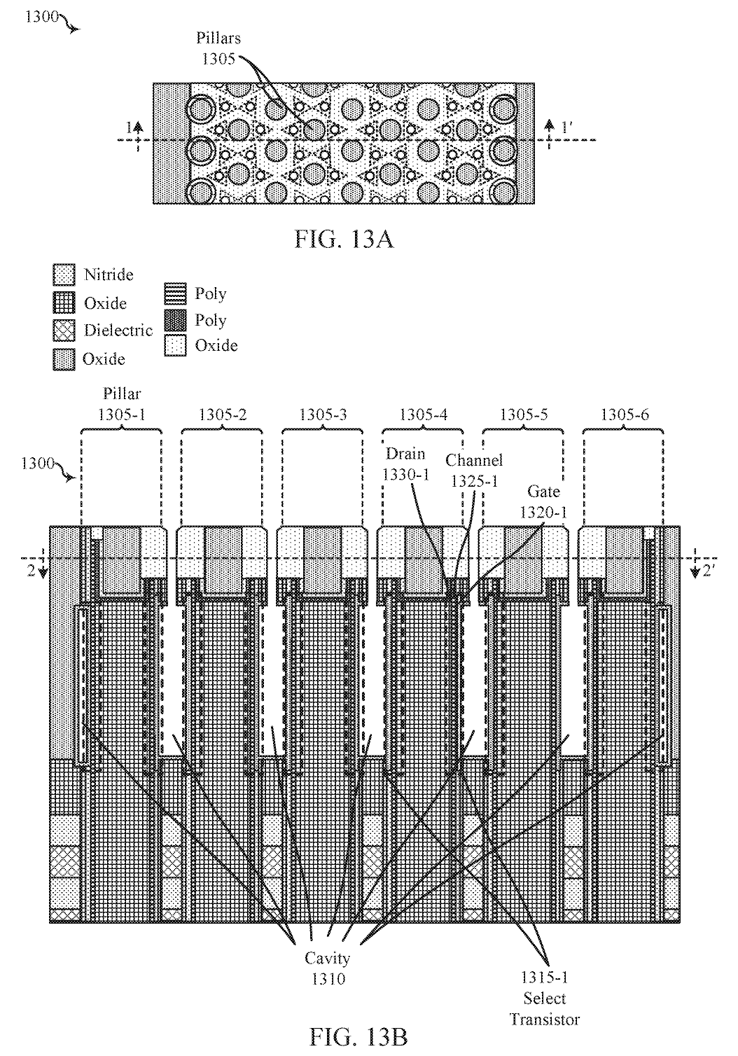

FIGS. 13A and 13B show different cross-sectional views of a material structure that supports pillar-embedded and integrated select transistors in accordance with examples as disclosed herein. FIG. 13A shows a top view of a first cross-section through the material structure 1300 indicated by line 2 – 2' (which may correspond to line 2 – 2' in FIG. 3). FIG. 13B shows a front view of a second cross-section through the material structure 1300 indicated by line 1 – 1' (which may correspond to line 1 – 1' in FIG. 3).

The material structure 1300 may be formed by adding (e.g., depositing, inserting) a gate oxide material within (e.g., on the walls of) the enlarged cavity 1210 formed in the material structure 1200 of FIGS. 12A and 12B. The cavity 1310 may remain after the gate oxide material is added. In some examples, the gate oxide material forms aspects of the gates for the select transistors resulting from the method of formation described herein.

The material structure 1300 may include select transistors (such as the first select transistor 1315-1). The select transistors may be embedded in the spaces between the pillars. The select transistors may include gates, channels, and drains (e.g., the first select transistor 1315-1 may have the first gate 1320-1, the first channel 1325-1, and the first drain 1330-1). Respective gates of the select transistors may be integrated and contiguous (e.g., may be integrally formed during a single gate oxide material deposition).

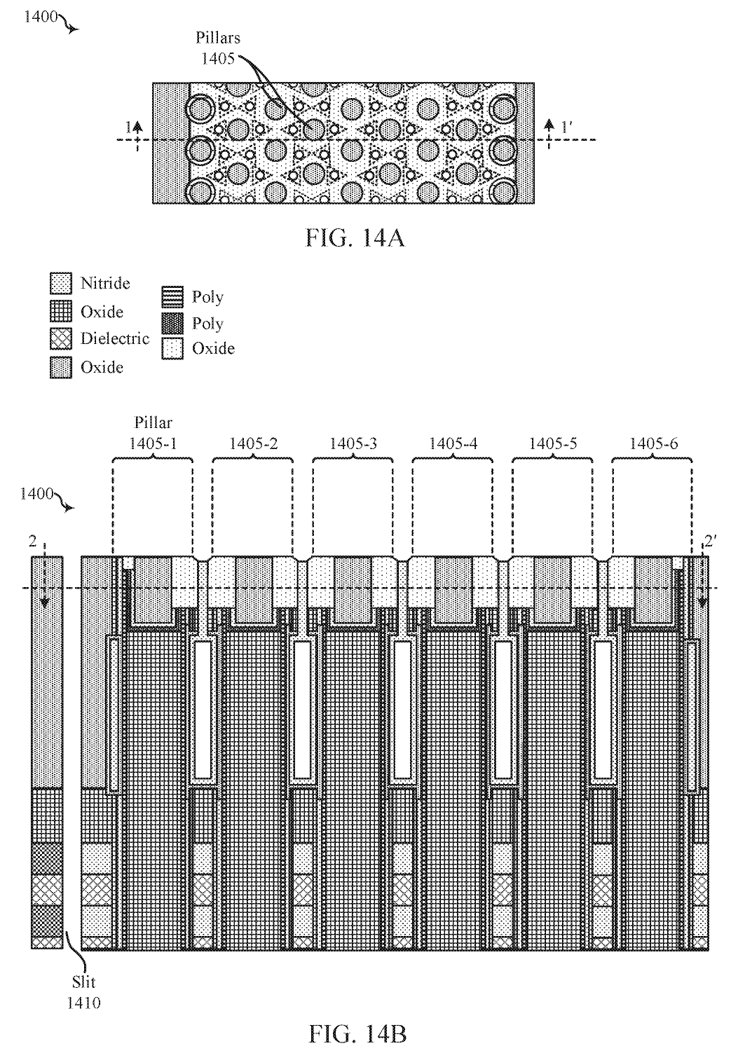

FIGS. 14A and 14B show different cross-sectional views of a material structure that supports pillar-embedded and integrated select transistors in accordance with examples as disclosed herein. FIG. 14A shows a top view of a first cross-section through the material structure 1400 indicated by line 2 – 2' (which may correspond to line 2 – 2' in FIG. 3). FIG. 14B shows a front view of a second cross-section through the material structure 1400 indicated by line 1 – 1' (which may correspond to line 1 – 1' in FIG. 3).

The material structure 1400 may be formed by filling the cavity 1310 of FIGS. 13A and 13B with a nitride material. In some examples, the nitride material does not fill the intermediary cavities (and is instead deposited on the walls of the intermediary cavities), leaving hollow portions between the pillars. After filling the cavity 1310, a portion of the material structure 1300 illustrated in FIGS. 13A and 13B may be removed (e.g., etched) to obtain the slit 1410. The slit 1410 may extend through the layered material stack of the material structure 1300 (e.g., to a substrate).

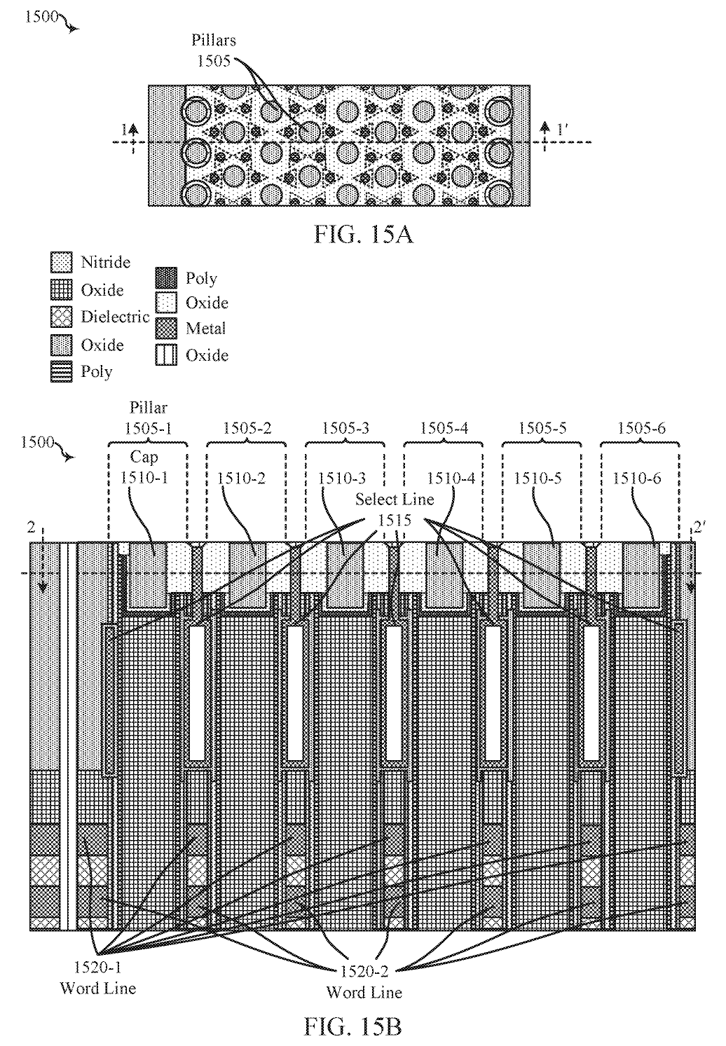

FIGS. 15A and 15B show different cross-sectional views of a material structure that supports pillar-embedded and integrated select transistors in accordance with examples as disclosed herein. FIG. 15A shows a top view of a first cross-section through the material structure 1500 indicated by line 2 – 2' (which may correspond to line 2 – 2' in FIG. 3). FIG. 15B shows a front view of a second cross-section through the material structure 1500 indicated by line 1 – 1' (which may correspond to line 1 – 1' in FIG. 3).

The material structure 1500 may be formed by removing (e.g., etching, patterning, exhuming) the nitride deposited into the cavity 1310 of FIGS. 13A and 13B as well as the nitride layers associated with the memory cells from the material structure 1400 illustrated in FIGS. 14A and 14B. Next, a high-K dielectric (e.g., AlOx) material may be added (e.g., deposited, inserted) within the cavity left by the exhumed nitride material. Then, a conductive metal (e.g., Tungsten) material may be added (e.g., deposited, inserted) within the cavity left after adding the high-K dielectric material. In some examples, the slit and the spaces between the pillars may provide access for removing the nitride material and for adding the metal material. After adding the conductive metal material, the slit may be filled with an oxide material. Also, the remaining cavities in the spaces between the pillars may be capped with the oxide material. In some examples, a top of the material structure may be planarized after the remaining cavities in the space between the pillars are capped.

The material structure 1500 may include word lines (e.g., the first word line 1520-1, and the second word line 1520-2) for accessing the memory cells. The material structure 1500 may also include select lines (e.g., the select line 1515) for accessing the select transistors.

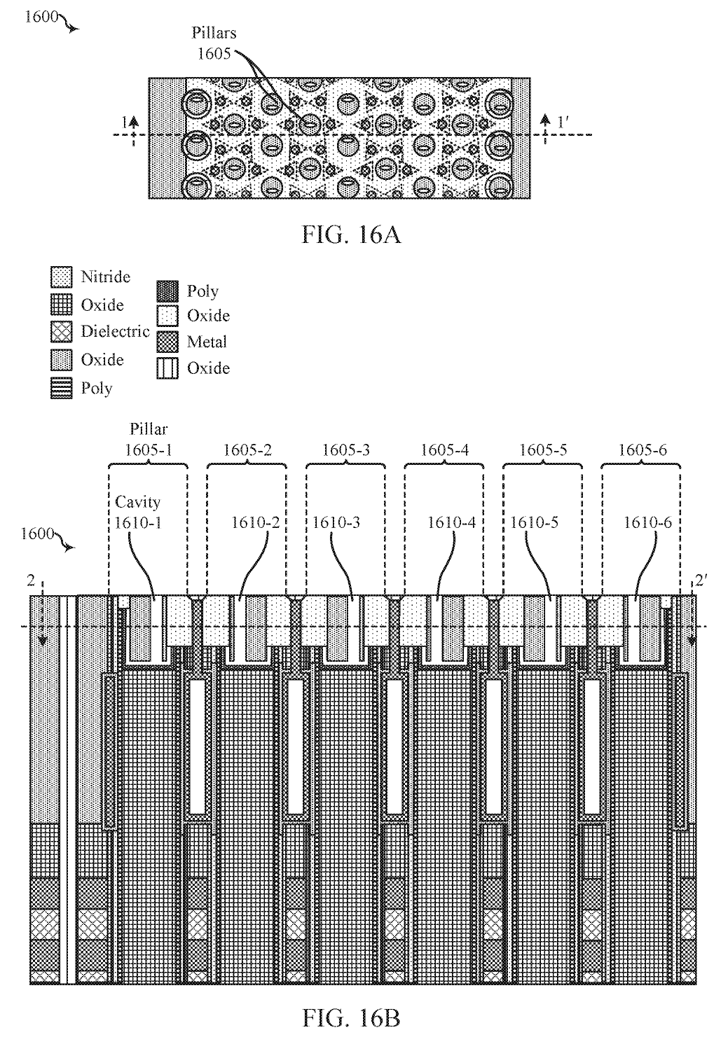

FIGS. 16A and 16B show different cross-sectional views of a material structure that supports pillar-embedded and integrated select transistors in accordance with examples as disclosed herein. FIG. 16A shows a top view of a first cross-section through the material structure 1600 indicated by line 2 – 2' (which may correspond to line 2 – 2' in FIG. 3). FIG. 16B shows a front view of a second cross-section through the material structure 1600 indicated by line 1 – 1' (which may correspond to line 1 – 1' in FIG. 3).

The material structure 1600 may be formed by removing (e.g., etching, patterning, exhuming) respective portions of the caps 1510 illustrated in FIGS. 15A and 15B to form respective cavities in the caps 1510. In some examples, the removed portion of the caps 1510 exposes the nitride material underneath the caps 1510. After exposing the nitride material, the nitride material may be exhumed to form the cavities (e.g., the first cavity 1610-1 through the sixth cavity 1610-6) in the caps illustrated in FIGS. 16A and 16B.

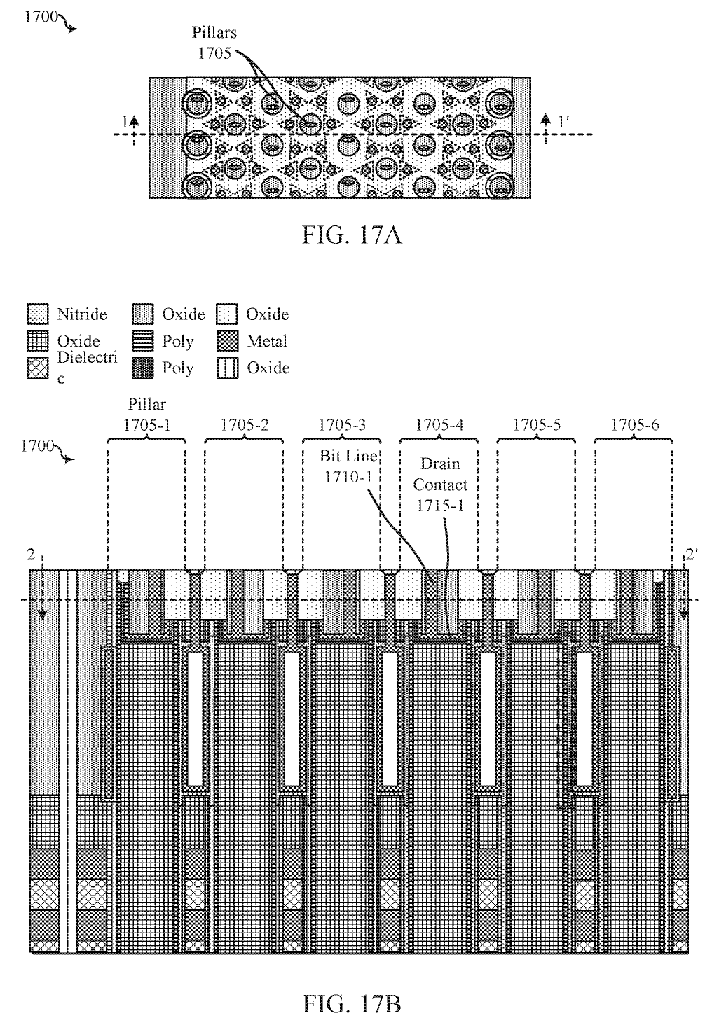

FIGS. 17A and 17B show different cross-sectional views of a material structure that supports pillar-embedded and integrated select transistors in accordance with examples as disclosed herein. FIG. 17A shows a top view of a first cross-section through the material structure 1700 indicated by line 2 – 2' (which may correspond to line 2 – 2' in FIG. 3). FIG. 17B shows a front view of a second cross-section through the material structure 1700 indicated by line 1 – 1' (which may correspond to line 1 – 1' in FIG. 3).

The material structure 1700 may be formed by filling the cavities 1610 illustrated in FIGS. 16A and 16B with a conductive metal material. In some examples, a top of the material structure may be planarized after the cavities 1610 are filled.

The material structure 1700 may include bit lines (e.g., the first bit line 1710-1) and drain contacts (e.g., the first drain contact 1715-1). The drain contacts may be in contact with a drain of the select transistors formed in the material structure 1700.

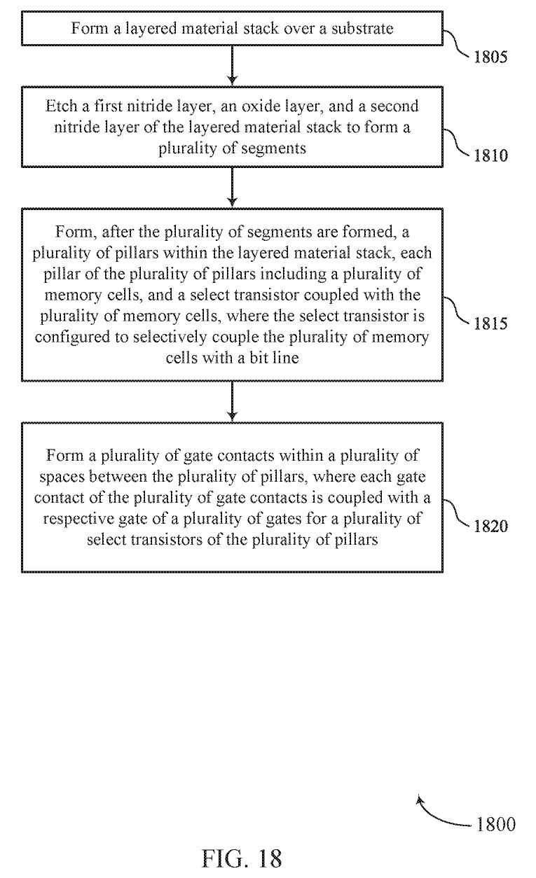

FIG. 18 shows a flowchart illustrating a method 1800 that supports pillar-embedded and integrated select transistors in accordance with examples as disclosed herein. The operations of method 1800 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 1805, the method may include forming a layered material stack over a substrate. The operations of 1805 may be performed in accordance with examples as disclosed herein.

At 1810, the method may include etching a first nitride layer, an oxide layer, and a second nitride layer of the layered material stack to form a plurality of segments. The operations of 1810 may be performed in accordance with examples as disclosed herein.

At 1815, the method may include forming, after the plurality of segments are formed, a plurality of pillars within the layered material stack, each pillar of the plurality of pillars including a plurality of memory cells, and a select transistor coupled with the plurality of memory cells, where the select transistor is configured to selectively couple the plurality of memory cells with a bit line. The operations of 1815 may be performed in accordance with examples as disclosed herein.

At 1820, the method may include forming a plurality of gate contacts within a plurality of spaces between the plurality of pillars, where each gate contact of the plurality of gate contacts is coupled with a respective gate of a plurality of gates for a plurality of select transistors of the plurality of pillars. The operations of 1820 may be performed in accordance with examples as disclosed herein.

In some examples, an apparatus as described herein may perform a method or methods, such as the method 1800. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming a layered material stack over a substrate; etching a first nitride layer, an oxide layer, and a second nitride layer of the layered material stack to form a plurality of segments; forming, after the plurality of segments are formed, a plurality of pillars within the layered material stack, each pillar of the plurality of pillars including a plurality of memory cells, and a select transistor coupled with the plurality of memory cells, where the select transistor is configured to selectively couple the plurality of memory cells with a bit line; and forming a plurality of gate contacts within a plurality of spaces between the plurality of pillars, where each gate contact of the plurality of gate contacts is coupled with a respective gate of a plurality of gates for a plurality of select transistors of the plurality of pillars.

Aspect 2: The method, apparatus, or non-transitory computer-readable medium of aspect 1, where forming the plurality of pillars includes operations, features, circuitry, logic, means, or instructions, or any combination thereof for etching through the layered material stack to a substrate to obtain a plurality of holes through the layered material stack; depositing, after etching through the layered material stack, a first oxide layer, a storage nitride layer, a tunnel oxide layer, and a channel polysilicon layer on the layered material stack; and partially filling, after depositing the oxide layer, the storage nitride layer, the tunnel oxide layer, and the channel polysilicon layer, a remaining portion of the plurality of holes with an oxide material.

Aspect 3: The method, apparatus, or non-transitory computer-readable medium of aspect 2, where forming the plurality of pillars includes operations, features, circuitry, logic, means, or instructions, or any combination thereof for depositing an n-doped polysilicon layer and a nitride layer on top of the oxide material; filling a second remaining portion of the plurality of holes with a second oxide material, where a plurality of caps are formed on top of the plurality of pillars based at least in part on filling the second remaining portion of the plurality of holes; and planarizing a top of the plurality of pillars.

Aspect 4: The method, apparatus, or non-transitory computer-readable medium of aspect 3, where forming the plurality of pillars includes operations, features, circuitry, logic, means, or instructions, or any combination thereof for exposing the plurality of caps and filling a plurality of spaces between the plurality of caps with a third oxide material.

Aspect 5: The method, apparatus, or non-transitory computer-readable medium of any of aspects 1 through 4, further including operations, features, circuitry, logic, means, or instructions, or any combination thereof for forming a plurality of holes within the plurality of spaces, where the second nitride layer is exposed based at least in part on forming the plurality of holes and etching the second nitride layer, where a plurality of cavities are formed within the plurality of spaces based at least in part on etching the second nitride layer.

Aspect 6: The method, apparatus, or non-transitory computer-readable medium of aspect 5, further including operations, features, circuitry, logic, means, or instructions, or any combination thereof for depositing a gate oxide material within the plurality of cavities, where the plurality of gates are formed for the plurality of select transistors based at least in part on depositing the gate oxide material.

Aspect 7: The method, apparatus, or non-transitory computer-readable medium of aspect 6, where forming the plurality of gate contacts further includes operations, features, circuitry, logic, means, or instructions, or any combination thereof for depositing a nitride material on the gate oxide material within the plurality of cavities; exhuming the nitride material and a plurality of nitride layers associated with a plurality of word lines; and depositing a conductive material within the plurality of cavities, where the conductive material is deposited after exhuming the nitride material.

Aspect 8: The method, apparatus, or non-transitory computer-readable medium of any of aspects 1 through 7, further including operations, features, circuitry, logic, means, or instructions, or any combination thereof for etching a plurality of holes in a plurality of caps at a top of the plurality of pillars, where a plurality of nitride materials is exposed based at least in part on etching the plurality of holes in the plurality of caps; exhuming the plurality of nitride materials to form a plurality of cavities; and filling the plurality of cavities with a conductive material, where a plurality of drain contacts are formed in a top portion of the plurality of pillars based at least in part on filling the plurality of cavities.

Aspect 9: The method, apparatus, or non-transitory computer-readable medium of aspect 8, further including operations, features, circuitry, logic, means, or instructions, or any combination thereof for filling, after filling the plurality of cavities, the plurality of holes with the conductive material, where a plurality of bit lines are formed in the top portion of the plurality of pillars based at least in part on filling the plurality of holes.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 10: A memory die, including: a substrate; a layered material stack over the substrate; a plurality of pillars within the layered material stack, where the plurality of pillars is distributed throughout the layered material stack with a first pillar of the plurality of pillars positioned centrally relative to other pillars of the plurality of pillars, and where each pillar of the plurality of pillars includes: a plurality of memory cells, and a select transistor coupled with the plurality of memory cells and a bit line, the select transistor being configured to selectively couple the plurality of memory cells with the bit line; and a plurality of gate contacts formed within a plurality of spaces between the plurality of pillars, each gate contact of the plurality of gate contacts being coupled with a respective gate of a plurality of gates for a plurality of select transistors of the plurality of pillars.

Aspect 11: The memory die of aspect 10, where the plurality of gate contacts are positioned below a top of the plurality of pillars.

Aspect 12: The memory die of any of aspects 10 through 11, further including: a plurality of drain contacts formed, where a top of each pillar of the plurality of pillars includes a respective drain contact of the plurality of drain contacts; and a plurality of bit lines, where each bit line of the plurality of bit lines is coupled with a respective select transistor of the plurality of select transistors via a respective drain contact of the plurality of drain contacts.

Aspect 13: The memory die of any of aspects 10 through 12, further including: a select line that is coupled with the plurality of select transistors of the plurality of pillars via respective gate contacts of the plurality of gate contacts, the select line being associated with a layer of the layered material stack.

Aspect 14: The memory die of any of aspects 10 through 13, further including: a plurality of blocks of memory cells of the plurality of memory cells, where each block of memory cells of the plurality of blocks of memory cells includes a plurality of subblocks of memory cells.

Aspect 15: The memory die of aspect 14, where a block of memory cells of the plurality of blocks of memory cells is partitioned on one side by a filled slit, and a subblock of memory cells of the plurality of subblocks of memory cells is partitioned on one side by a filled segment.

Aspect 16: The memory die of any of aspects 10 through 15, further including: a plurality of word lines coupled with the plurality of memory cells, each word line of the plurality of word lines associated with a respective layer of the layered material stack.

An apparatus is described. The following provides an overview of aspects of the apparatus as described herein:

Aspect 17: A memory die, including: a layered material stack; and a plurality of pillars extending through the layered material stack, where the plurality of pillars is distributed throughout the layered material stack with a first pillar of the plurality of pillars positioned centrally relative to other pillars of the plurality of pillars, and where each pillar of the plurality of pillars includes: a respective plurality of memory cells, and a respective select transistor coupled with the respective plurality of memory cells, and where a first wall of a first pillar of the plurality of pillars forms a channel for a select transistor of the first pillar and for a plurality of memory cells, and where a second wall of the first pillar includes a first portion that forms a gate of the select transistor and a second portion that forms a plurality of storage elements for the plurality of memory cells.

Aspect 18: The memory die of aspect 17, where a third wall of the first pillar includes a first portion that forms a gate contact for the select transistor and a second portion that forms a plurality of gates for the plurality of memory cells.

Aspect 19: The memory die of any of aspects 17 through 18, where a select line coupled with a plurality of gates of a plurality of select transistors includes a plurality of hollow portions at a plurality of spaces in between the plurality of pillars.

Aspect 20: The memory die of any of aspects 17 through 19, where the plurality of pillars further includes: a plurality of drain contacts positioned within the plurality of pillars at respective positions above a plurality of select transistors, where each drain contact is coupled with a respective select transistor of the plurality of select transistors.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three-dimensional structure where two dimensions are greater than a third, e.g., a thin film. Layers or levels may include different elements, components, or materials, or combinations thereof. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor’s threshold voltage is applied to the transistor gate. The transistor may be “off” or “deactivated” if a voltage less than the transistor’s threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory die, comprising:
a substrate;
a layered material stack over the substrate;
a plurality of pillars within the layered material stack, wherein the plurality of pillars is distributed throughout the layered material stack with a first pillar of the plurality of pillars positioned centrally relative to other pillars of the plurality of pillars, and wherein each pillar of the plurality of pillars comprises:
a plurality of memory cells, and
a select transistor coupled with the plurality of memory cells and a bit line, the select transistor being configured to selectively couple the plurality of memory cells with the bit line; and
a plurality of gate contacts formed within a plurality of spaces between the plurality of pillars, each gate contact of the plurality of gate contacts being coupled with a respective gate of a plurality of gates for a plurality of select transistors of the plurality of pillars.

2. The memory die of claim 1, wherein the plurality of gate contacts are positioned below a top of the plurality of pillars.

3. The memory die of claim 1, further comprising:
a plurality of drain contacts, wherein a top of each pillar of the plurality of pillars comprises a respective drain contact of the plurality of drain contacts; and
a plurality of bit lines, wherein each bit line of the plurality of bit lines is coupled with a respective select transistor of the plurality of select transistors via a respective drain contact of the plurality of drain contacts.

4. The memory die of claim 1, further comprising:
a select line that is coupled with the plurality of select transistors of the plurality of pillars via respective gate contacts of the plurality of gate contacts, the select line being associated with a layer of the layered material stack.

5. The memory die of claim 1, further comprising:
a plurality of blocks of memory cells of the plurality of memory cells, wherein each block of memory cells of the plurality of blocks of memory cells comprises a plurality of subblocks of memory cells.

6. The memory die of claim 5, wherein a block of memory cells of the plurality of blocks of memory cells is partitioned on one side by a filled slit, and wherein a subblock of memory cells of the plurality of subblocks of memory cells is partitioned on one side by a filled segment.

7. The memory die of claim 1, further comprising:
a plurality of word lines coupled with the plurality of memory cells, each word line of the plurality of word lines associated with a respective layer of the layered material stack.

8. A method of formation, comprising:
forming a layered material stack over a substrate;
etching a first nitride layer, an oxide layer, and a second nitride layer of the layered material stack to form a plurality of segments;
forming, after the plurality of segments are formed, a plurality of pillars within the layered material stack, each pillar of the plurality of pillars comprising:
a plurality of memory cells, and
a select transistor coupled with the plurality of memory cells, wherein the select transistor is configured to selectively couple the plurality of memory cells with a bit line; and
forming a plurality of gate contacts within a plurality of spaces between the plurality of pillars, wherein each gate contact of the plurality of gate contacts is coupled with a respective gate of a plurality of gates for a plurality of select transistors of the plurality of pillars.

9. The method of formation of claim 8, wherein forming the plurality of pillars comprises:
etching through the layered material stack to the substrate to obtain a plurality of holes through the layered material stack;
depositing, after etching through the layered material stack, a first oxide layer, a storage nitride layer, a tunnel oxide layer, and a channel polysilicon layer on the layered material stack; and
partially filling, after depositing the oxide layer, the storage nitride layer, the tunnel oxide layer, and the channel polysilicon layer, a remaining portion of the plurality of holes with an oxide material.

10. The method of formation of claim 9, wherein forming the plurality of pillars comprises:
depositing an n-doped polysilicon layer and a nitride layer on top of the oxide material;
filling a second remaining portion of the plurality of holes with a second oxide material, wherein a plurality of caps are formed on top of the plurality of pillars based at least in part on filling the second remaining portion of the plurality of holes; and
planarizing a top of the plurality of pillars.

11. The method of formation of claim 10, wherein forming the plurality of pillars comprises:
exposing the plurality of caps; and
filling a plurality of spaces between the plurality of caps with a third oxide material.

12. The method of formation of claim 8, further comprising:
forming a plurality of holes within the plurality of spaces, wherein the second nitride layer is exposed based at least in part on forming the plurality of holes; and
etching the second nitride layer, wherein a plurality of cavities are formed within the plurality of spaces based at least in part on etching the second nitride layer.

13. The method of formation of claim 12, further comprising:
depositing a gate oxide material within the plurality of cavities, wherein the plurality of gates are formed for the plurality of select transistors based at least in part on depositing the gate oxide material.

14. The method of formation of claim 13, wherein forming the plurality of gate contacts further comprises:
depositing a nitride material on the gate oxide material within the plurality of cavities;
exhuming the nitride material and a plurality of nitride layers associated with a plurality of word lines; and
depositing a conductive material within the plurality of cavities, wherein the conductive material is deposited after exhuming the nitride material.

15. The method of formation of claim 8, further comprising:
etching a plurality of holes in a plurality of caps at a top of the plurality of pillars, wherein a plurality of nitride materials is exposed based at least in part on etching the plurality of holes in the plurality of caps;
exhuming the plurality of nitride materials to form a plurality of cavities; and
filling the plurality of cavities with a conductive material, wherein a plurality of drain contacts are formed in a top portion of the plurality of pillars based at least in part on filling the plurality of cavities.

16. The method of formation of claim 15, further comprising:
filling, after filling the plurality of cavities, the plurality of holes with the conductive material, wherein a plurality of bit lines are formed in the top portion of the plurality of pillars based at least in part on filling the plurality of holes.

17. A memory die, comprising:
a layered material stack; and
a plurality of pillars extending through the layered material stack, wherein the plurality of pillars is distributed throughout the layered material stack with a first pillar of the plurality of pillars positioned centrally relative to other pillars of the plurality of pillars, and wherein each pillar of the plurality of pillars comprises:
a respective plurality of memory cells, and
a respective select transistor coupled with the respective plurality of memory cells, and
wherein a first wall of the first pillar of the plurality of pillars forms a channel for a select transistor of the first pillar and for a plurality of memory cells, and
wherein a second wall of the first pillar comprises a first portion that forms a gate of the select transistor and a second portion that forms a plurality of storage elements for the plurality of memory cells.

18. The memory die of claim 17, wherein a third wall of the first pillar comprises a first portion that forms a gate contact for the select transistor and a second portion that forms a plurality of gates for the plurality of memory cells.

19. The memory die of claim 17, wherein a select line coupled with a plurality of gates of a plurality of select transistors comprises a plurality of hollow portions at a plurality of spaces in between the plurality of pillars.

20. The memory die of claim 17, wherein the plurality of pillars further comprises:
a plurality of drain contacts positioned within the plurality of pillars at respective positions above a plurality of select transistors, wherein each drain contact is coupled with a respective select transistor of the plurality of select transistors.
